(19) United States
(12) Patent Application Publication
(10) Pub. No.: US 2022/0406695 A1
(43) Pub. Date: Dec. 22, 2022

(54) SEMICONDUCTOR DEVICE PACKAGE HAVING A BALL GRID ARRAY WITH MULTIPLE SOLDER BALL MATERIALS

(71) Applicant: Western Digital Technologies, Inc., San Jose, CA (US)

(72) Inventors: Siqi Zhang, Shanghai (CN); Xu Wang, Shanghai (CN); Wei Wang, Shanghai (CN); Yangming Liu, Shanghai (CN); Pradeep Rai, Fremont, CA (US)

(73) Assignee: Western Digital Technologies, Inc., San Jose, CA (US)

(21) Appl. No.: 17/354,096

(22) Filed: Jun. 22, 2021

(51) Int. Cl. H01L 23/498; H01L 23/00

(52) U.S. Cl. CPC H01L 23/49816; H01L 24/83; H01L 2924/15311; H01L 2924/014; H01L 2924/06; H01L 2924/15701

(57) ABSTRACT

A semiconductor device package includes a semiconductor device with a ball grid array having a first subset of solder balls composed of metallic solder, and a second subset of solder balls composed of a composite material that includes a polymer core surrounded by a solder layer. The solder balls of the second subset can have a lower elastic modulus than the solder balls of the first subset and resist cracking due to thermal stresses on the semiconductor device package. In one embodiment, at least a portion of the second subset of solder balls is located on the periphery of the ball grid array such that the first subset of solder balls may be surrounded, at least partially, by the second subset of solder balls.

### BACKGROUND

The present disclosure relates to a semiconductor device package having a ball grid array that includes multiple solder ball materials. A semiconductor device package according to some embodiments includes a ball grid array having a first subset of solder balls made from a first material, and at least a second subset of solder balls made from a second material that has a lower elastic modulus than the first material.

Bond pads on the active surface of a semiconductor device (e.g., an integrated circuit die) may include an array of solder balls for mounting onto a substrate. The substrate may be, for example, a printed circuit board (PCB), a carrier, and/or another semiconductor device having contact pads for connecting to the solder balls. The array of solder balls, generally referred to as a ball grid array (BGA), provides electrical and mechanical connections between the semiconductor device and the substrate. To attach the BGA to the substrate, a heating process (e.g., a reflow process) is typically used to melt the solder balls onto the contact pads.

Conventional solder balls may be composed entirely of metal or metal alloy solders, for example tin, tin alloys, tin/lead alloys, silver alloys, etc., and may be configured to melt at a temperature in the range of about 175° C. to about 250° C. These conventional solder balls, however, are not mechanically compliant. As a result, bending of the substrate or other components of the semiconductor device package due to thermal stresses and/or mechanical stresses (e.g., vibration) can cause the solder ball joints to crack and fracture. This in turn may cause electrical and/or mechanical disconnection between the semiconductor device and the substrate. For example, heat generated by the semiconductor device during use and/or temperature changes in the surrounding environment can result in thermal stresses due to differences in the coefficient of thermal expansion (CTE) between the substrate and other components. The substrate and other components of the semiconductor device package may expand or contract at different rates when subjected to the temperature changes, resulting in stress and cracking at the solder balls. It would therefore be advantageous to be able to improve the BGA to resist cracking during such stresses.

### SUMMARY

The present disclosure, according to some embodiments, provides a semiconductor device package that includes a semiconductor device having a ball grid array composed of solder balls of different materials. The ball grid array, in some embodiments, includes a first subset of solder balls composed of a first material and a second subset of solder balls composed of a second material that is different than the first material. In some embodiments, the first material has an elastic modulus that is greater than an elastic modulus of the second material. In some embodiments, the first material is a metallic solder, and the second material is a composite material including at least one polymer. In some embodiments, the composite material includes a core made from the at least one polymer, and further includes a solder layer surrounding the core. In some embodiments, the solder layer of the second material has a melting temperature that is the same as, or approximately the same as, the melting temperature of the metallic solder of the first material. In some embodiments, the second material further includes one or more inner layers disposed between the core and the solder layer. In some embodiments, the one or more inner layers includes one or more metallic layers having a melting temperature greater than the melting temperature of the solder layer.

In some embodiments, at least a portion of the second subset of solder balls is located on a periphery of the ball grid array. In some embodiments, at least a portion of the second subset of solder balls are positioned at one or more corners of the ball grid array. In some embodiments, a solder ball of the second subset of solder balls is positioned at each corner of the ball grid array. In some embodiments, the ball grid array includes one or more peripheral rows and/or one or more peripheral columns that are composed entirely of solder balls of the second subset of solder balls. In some embodiments, all of the solder balls of the second subset of solder balls are positioned in the one or more peripheral rows and/or the one or more peripheral columns of the ball grid array. In some embodiments, each solder ball of the first subset is located between at least two solder balls of the second subset in a same column or row of the ball grid array. In some embodiments, the first subset of solder balls is surrounded, partially or entirely, by the second subset of solder balls.

In some embodiments, a substrate is coupled electrically and mechanically to the semiconductor device by the ball grid array. In some embodiments, an underfill material is added between the substrate and the semiconductor device. In other embodiments, an underfill material is not present between the semiconductor device and the substrate. In some embodiments, at least a portion of the second subset of solder balls may be electrically isolated from the semiconductor device such that this portion of the solder balls does not provide electrical connections between the semiconductor device and the substrate. In some embodiments, all the solder balls of the second subset are electrically isolated from the semiconductor device.

In further embodiments, a semiconductor device package includes substrate means for providing electrical interconnections, integrated circuit means for outputting electrical signals to the substrate means, first solder ball means disposed between the integrated circuit means and the substrate means for electrically coupling the integrated circuit means to the substrate means, and second solder ball means disposed between the integrated circuit means and the substrate means for mechanically coupling the integrated circuit means to the substrate. The second solder ball means may include a material of lower elastic modulus and/or higher tensile strength (e.g., ultimate tensile strength) than the first solder ball means. In some embodiments, the first solder ball means and the second solder ball means are arranged in an array, wherein the second solder ball means are positioned at least at one or more corners of the array. In some embodiments, the first solder ball means is surrounded by the second solder ball means. In some embodiments, at least a portion of the second solder ball means is electrically isolated from the integrated circuit means.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

FIG. 1A is a plan view illustrating a semiconductor device including a BGA on a side of a semiconductor device according to one example;

FIG. 1B is cross-sectional view of the semiconductor device of FIG. 1A taken along the plane designated by line 1B-1B;

FIG. 1C is a partial cross-sectional view of the semiconductor device of FIG. 1B and a substrate, the BGA being in alignment with contact pads of the substrate;

FIG. 1D is a partial cross-sectional view of the semiconductor device coupled to the substrate of FIG. 1C by the BGA;

FIG. 1E is a partial cross-sectional view of the semiconductor device coupled to the substrate of FIG. 1C by the BGA, further showing an underfill material disposed between the semiconductor device and the substrate;

FIG. 2A is a cross-sectional image of an example row of 14 conventional solder ball joints in a BGA after being cycled between −40° C. and 125° C. for 1000 cycles;

FIG. 2B is an enlarged cross-sectional view of the 1^{st} through 7^{th} solder balls shown in FIG. 2A;

FIG. 2C is an enlarged cross-sectional view of the 8^{th} through 14^{th} solder balls shown in FIG. 2A;

FIG. 3A is a heat map of simulated strain energy density on a square BGA according to a further example;

FIG. 3B is an enlarged perspective view of the corner region designated 3B in the heat map of FIG. 3A;

FIG. 3C is a graph showing the relation between the number of temperature cycles to failure and simulated strain energy density according to one example;

FIG. 4A is a plan view illustrating a semiconductor device including a BGA on a side of a semiconductor device according to some embodiments, where the BGA includes a first subset of solder balls (empty circles) and a second subset of solder balls (patterned circles), the second subset of solder balls being positioned at the corners of the BGA;

FIG. 4B is cross-sectional view of the semiconductor device of FIG. 4A taken along the plane designated by line 4B-4B;

FIG. 4C is a partial cross-sectional view of the semiconductor device of FIG. 4B coupled to a substrate by the BGA;

FIG. 5A is a plan view illustrating a semiconductor device including a BGA on a side of a semiconductor device according to some embodiments, where the BGA includes a first subset of solder balls (empty circles) and a second subset of solder balls (patterned circles), the second subset of solder balls being positioned at the corners of the BGA and along peripheral rows/columns of the BGA;

FIG. 5B is cross-sectional view of the semiconductor device of FIG. 5A taken along the plane designated by line 5B-5B;

FIG. 5C is a partial cross-sectional view of the semiconductor device of FIG. 5B coupled to a substrate by the BGA;

FIG. 6 is a plan view illustrating a semiconductor device including a BGA on a side of a semiconductor device according to some embodiments, where the BGA includes a first subset of solder balls (empty circles) and a second subset of solder balls (patterned circles), the second subset of solder balls being positioned at corner regions of the BGA;

FIG. 7 is a plan view illustrating a semiconductor device including a BGA on a side of a semiconductor device according to some embodiments, where the BGA includes a first subset of solder balls (empty circles) and a second subset of solder balls (patterned circles), the second subset of solder balls being asymmetrically arranged on the BGA;

FIG. 8 is a plan view illustrating a semiconductor device including a BGA on a side of a semiconductor device according to some embodiments, where the BGA includes a first subset of solder balls (empty circles) and a second subset of solder balls (patterned circles), the second subset of solder balls being positioned along peripheral columns of the BGA;

FIG. 9 is a plan view illustrating a semiconductor device including a BGA on a side of a semiconductor device according to some embodiments, where the BGA includes a first subset of solder balls (empty circles) and a second subset of solder balls (patterned circles), the second subset of solder balls being positioned along peripheral rows of the BGA;

FIG. 10 is a plan view illustrating a semiconductor device including a BGA on a side of a semiconductor device according to some embodiments, where the BGA includes a first subset of solder balls (empty circles) and a second subset of solder balls (patterned circles), the second subset of solder balls being positioned along peripheral columns and peripheral rows of the BGA;

FIG. 11 is a plan view illustrating a semiconductor device including a BGA on a side of a semiconductor device according to some embodiments, where the BGA includes a first subset of solder balls (empty circles) and a second subset of solder balls (patterned circles), the second subset of solder balls further being positioned in one or more rows and/or columns adjacent to the peripheral rows/columns; and

FIG. 12 is an enlarged cross-sectional view of a solder ball of the second subset according to some embodiments, illustrating a core material, outer layer, and one or more inner layers disposed between the core material and outer layer.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

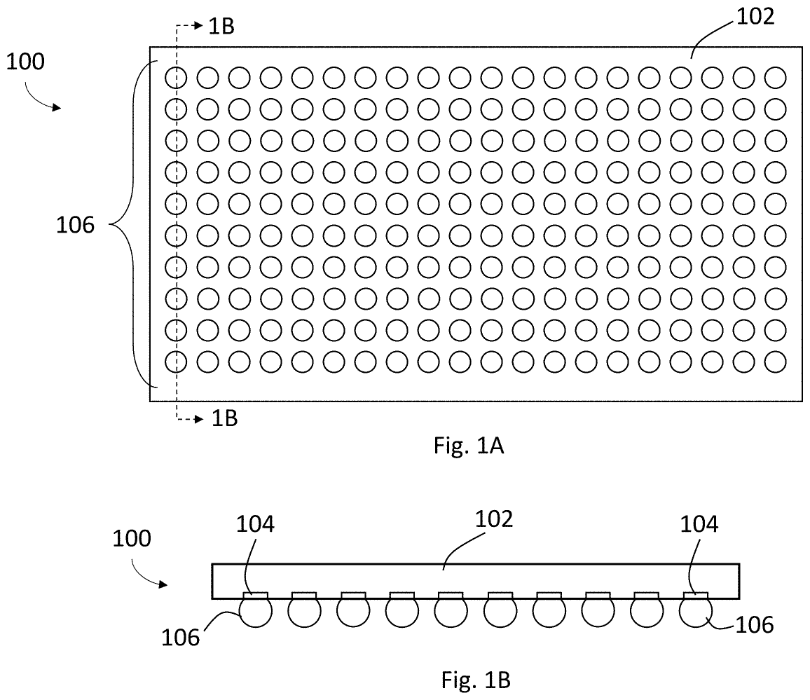

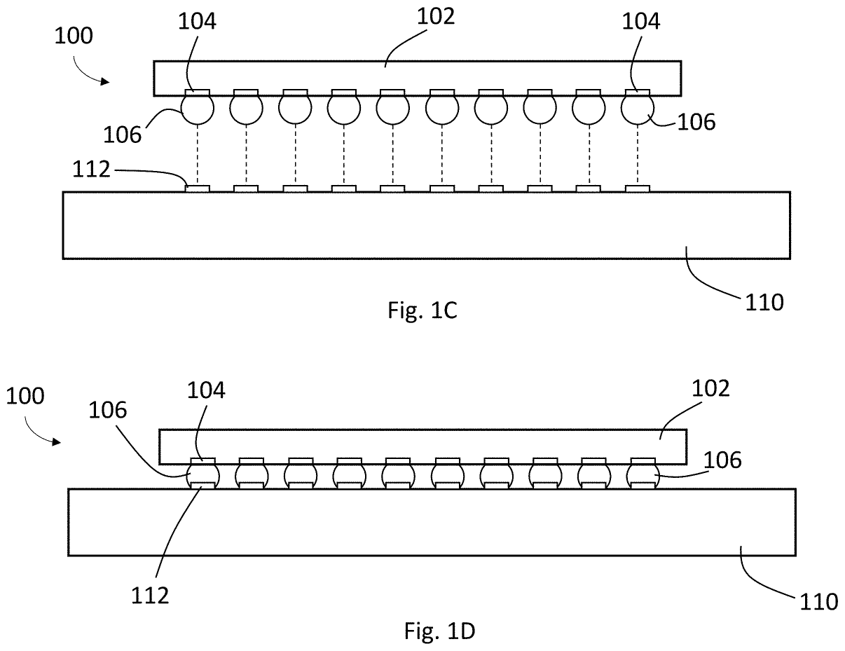

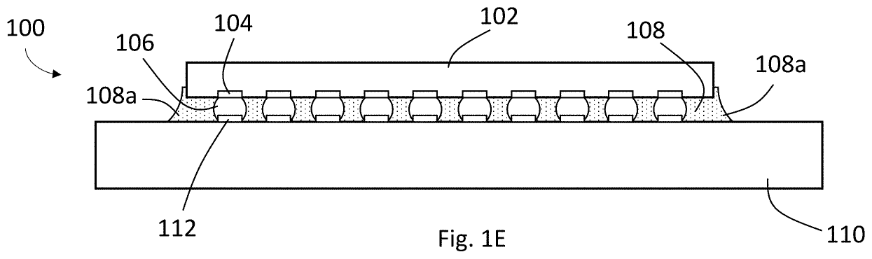

FIGS. 1A and 1B illustrate an example semiconductor device package 100 that includes a semiconductor device 102 (e.g., an integrated circuit (IC) die) and a plurality of solder balls 106 coupled to an active side of semiconductor device 102 in an array (BGA). Each solder ball 106 may be a conventional solder ball that is composed entirely of the same metallic solder material, e.g., tin, tin alloys, tin/lead alloys, silver alloys, etc. For example, solder ball 106 may be composed of a tin-copper (Sn—Cu) alloy, tin-lead (Sn—Pb) alloy, or tin-silver-copper (Sn—Ag—Cu) alloy. As depicted in FIG. 1A, solder balls 106 of the BGA may be arranged in a plurality of rows and/or columns that form a grid. For instance, the illustrated example shows two hundred solder balls 106 that are arranged in ten horizontal rows and twenty vertical columns. However, the total number of solder balls 106, and their arrangement are not necessarily limited to this specific configuration. As shown in the cross-sectional view of FIG. 1B, solder balls 106 may each be attached to a separate bond pad 104 on a surface of semiconductor device 102.

As further illustrated in FIGS. 1C and 1D, solder balls 106 are configured to electrically and/or mechanically connect semiconductor device 102 to a substrate 110. Substrate 110 may include, for example, a PCB, a chip carrier, and/or another semiconductor device. A surface of substrate 110 may include a plurality of contact pads 112 that are each configured to make contact with a separate solder ball 106. To connect semiconductor device 102 with substrate 110, semiconductor device 102 may be positioned such that solder balls 106 are brought into alignment with contact pads 112 (FIG. 1C), and then semiconductor device 102 and substrate 110 are moved toward each other until solder balls 106 are brought into abutment against contact pads 112. A heating process, e.g, a standard reflow process, may then be used to heat and melt solder balls 106 onto contact pads 112. For example, each solder ball 106 may be composed entirely of a solder material that is configured to melt at a temperature from about 175° C. to about 250° C.

Referring now to FIG. 1E, in order to strengthen the attachment of semiconductor device 102 and substrate 110, an underfill material 108 may be applied between semiconductor device 102 and substrate 110 to improve adhesion and/or distribute thermal stresses. Underfill material 108 may include, for example, a non-conductive resin (e.g. an epoxy resin) that is injected into the space between semiconductor device 102 and substrate 110 and subsequently cured. However, use of underfill material 108 requires additional, often complex, manufacturing steps as well as added costs. Furthermore, underfill material 108 may include a fillet 108a on substrate 110 that extends beyond the edges of semiconductor device 102, reducing the area on substrate 110 that is available for mounting other components.

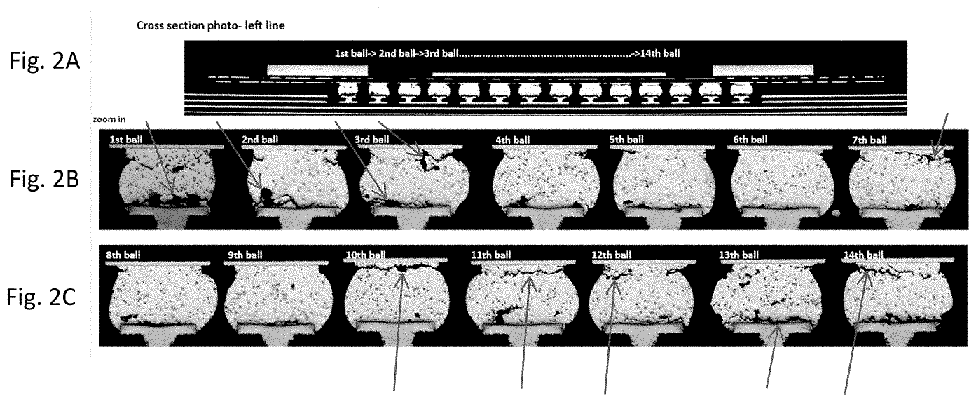

As previously described, conventional solder balls (e.g., solder balls 106) may be prone to cracking when the semiconductor device package is subjected to thermal and/or mechanical stresses. FIGS. 2A-2C provide cross-sectional images of a row of 14 conventional solder ball joints in a BGA after being subjected to a temperature cycling test (TCT). In this example, the solder balls were composed of Sn—Ag—Cu alloy, with a silver content of about 1.2%. In particular, the solder balls were cycled between −40° C. and 125° C. for 1000 cycles. FIG. 2A provides a view of the entire row of 14 solder balls, FIG. 2B provides an enlarged view of the 1^{st} through 7^{th} solder balls, and FIG. 2C provides an enlarged view of the 8^{th} through 14^{th} solder balls. As shown in these images, many of the solder balls developed cracks in their material, highlighted by the arrows. While the 7^{th} solder ball located in the middle of the row also developed a crack, it was found that the most prominent cracks occurred in the solder balls that are closest to either ends of the row (e.g., 1^{st}-3^{rd} balls and 10^{th}-14^{th} solder balls). Without wishing to be bound by theory, it is believed that the ends of the row were subjected to the greatest strain from the thermal cycling.

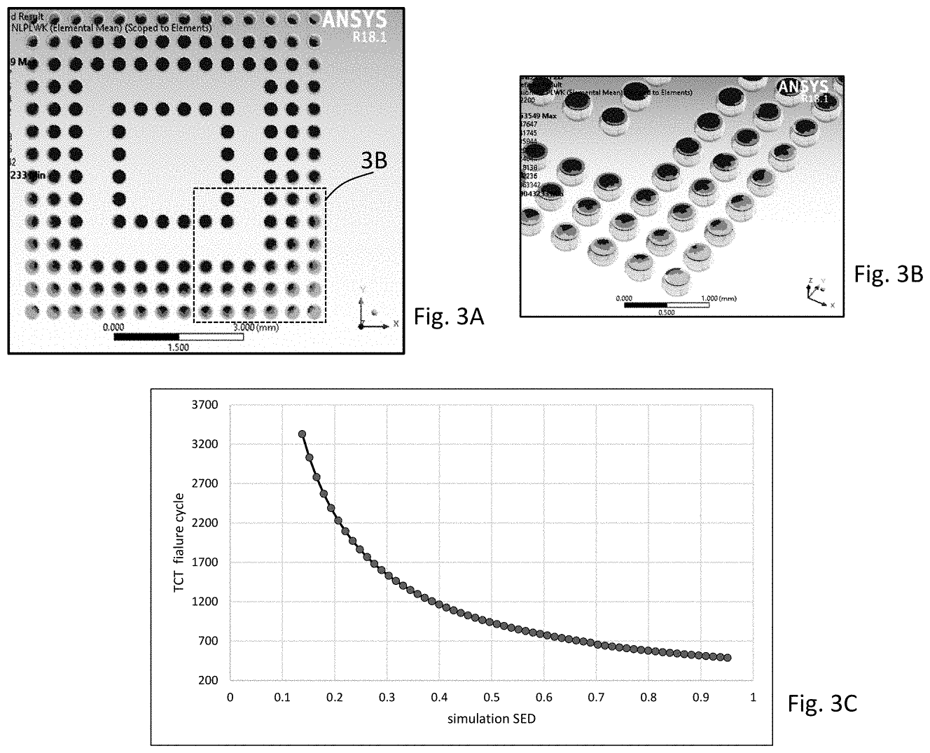

FIGS. 3A and 3B show a heat map of simulated strain energy density on a square BGA according to another example. FIG. 3B is an enlarged, perspective view of the lower, right corner portion of the BGA shown in FIG. 3A. As demonstrated in this simulation, it was found that the highest strain occurred among the solder balls located at the outer-most rows of the BGA, particularly at the corner regions. Conversely, the solder balls positioned closer to the center of the BGA were found to have the lowest amount of strain. Because the outer-most solder balls may potentially encounter the greatest strain, they may be more prone to cracking and failure. It has been found that strain energy density may serve as an indicator of TCT performance. More particularly, strain energy density is conversely related to TCT performance such that the higher the strain energy density, the lower the number of temperature cycles before failure. FIG. 3C is a graph showing the relationship of TCT failure cycle and simulated strain energy density (SED) according to one example. As shown in FIG. 3C, the highest SED (about 0.95) had a TCT failure at about 489 cycles, while the lowest SED (about 0.14) had a TCT failure at about 3330 cycles.

According to certain embodiments of the present disclosure, it is believed that replacing the conventional solder balls positioned at the areas of greatest strain with solder balls composed of materials having greater resilience may prevent or reduce the amount of solder ball cracking, and therefore improve reliability of the BGA. In some embodiments, the present disclosure provides a semiconductor device package that includes a BGA having at least a first subset of solder balls made from a first material, and a second subset of solder balls made from a second material that is different than the first material. The first subset of solder balls may be, for example, entirely metallic solder balls (e.g., tin, tin alloy, tin/lead alloy, etc.), while the second subset of solder balls may be composite solder balls made from a combination of metallic and polymer (e.g., plastic) materials. As will be described further herein, in some embodiments, the solder balls of the second subset may include a polymer core surrounded by one or more layers of metal or metal alloy. In some embodiments, the solder balls of the second subset may include an outer layer of solder that has the same or similar melting temperature as the solder balls of the first subset. In some embodiments, the solder balls of the second subset may have a lower elastic modulus than the solder balls of the first subset. In some embodiments, the solder balls of the second subset may have a lower coefficient of thermal expansion (CTE) than the solder balls of the first subset. In some embodiments, the solder balls of the second subset may have a CTE that more closely matches the CTE of the substrate. In some embodiments, the solder balls of the second subset have a greater toughness than the solder balls of the first subset, toughness being the ability of a material to absorb energy and plastically deform without fracturing. In some embodiments, the solder balls of the second subset have a higher tensile strength than the solder balls of the first subset. In some embodiments, having a higher tensile strength may allow the solder balls of the second subset to withstand stress/strain better than the solder balls of the first subset. In some embodiments, the solder balls of the first subset may still have certain properties that are desirable over the solder balls of the second subset, for example, better electrical conductivity, lower cost, etc. Accordingly, in some embodiments, it may be preferred to include both solder ball types of the first subset and the second subset in a BGA, rather than only one or the other.

In some embodiments, the second subset of solder balls may be positioned in the BGA in areas that could potentially encounter the greatest strain. In some embodiments, for example, the second subset of the solder balls may be positioned at a periphery of the BGA, e.g., along the outermost rows and/or columns of the BGA. In some embodiments, the second subset of solder balls may only be positioned in one or more of the outermost rows and/or columns of the BGA. In other embodiments, the second subset of solder balls may also be located within one or more rows and/or columns that are adjacent to the outermost rows and/or columns of the BGA. In some embodiments, the second subset of the solder balls may be positioned at least at one or more corners or corner regions of the BGA, possibly at all of the corners or corner regions of the BGA. In some embodiments, the solder balls of the first subset of solder balls may be surrounded, partially or entirely, by solder balls of the second subset. In some embodiments, each solder ball of the first subset of solder balls may be disposed in a row and/or column between two or more solder balls of the second subset.

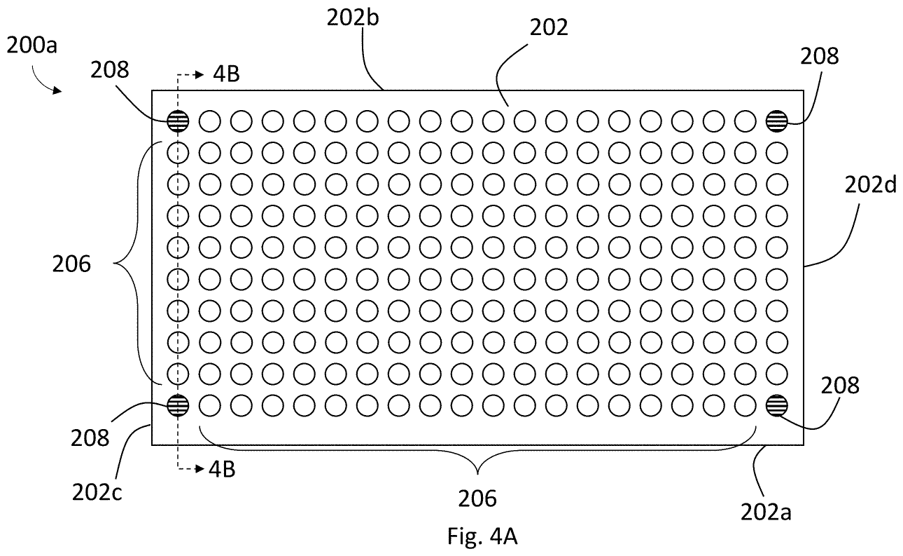

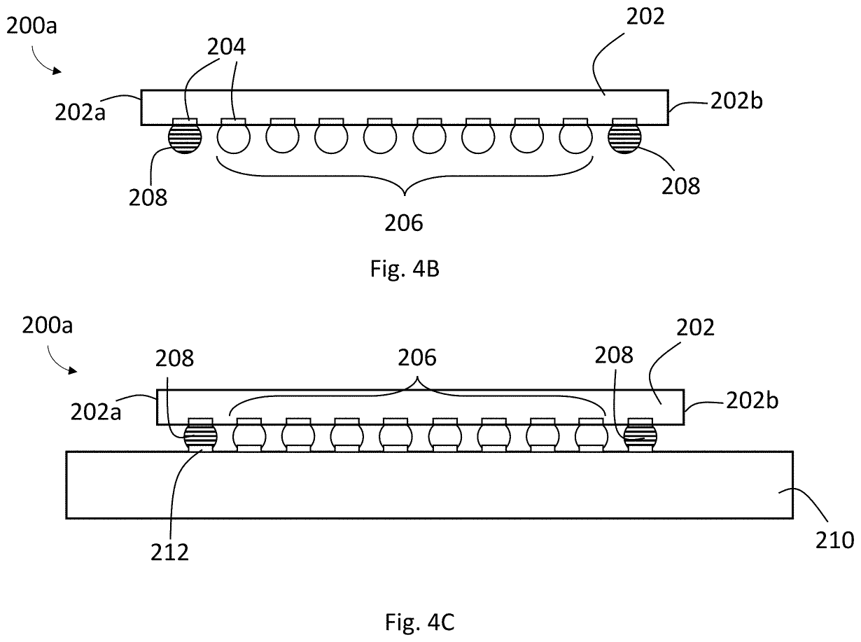

FIG. 4A shows a plan view of a BGA of a semiconductor device package 200a according to certain embodiments. The BGA is positioned on a side of semiconductor device 202 and includes a first subset of solder balls 206 (each depicted as an empty circle) and a second subset of solder balls 208 (each depicted as a patterned circle). Semiconductor device 202 may be, for example, an integrated circuit (IC) die or chip, e.g., a microprocessor, a flip-chip die, controller die, application-specific integrated circuit (ASIC) die, etc. In some embodiments, solder balls 206 of the first subset are composed of a different material than solder balls 208 of the second subset, as described above. For example, in some embodiments, solder balls 206 are composed entirely of a metallic solder (e.g., tin solder, tin alloy, tin/lead alloy, etc.), while each solder ball 208 of the second subset may be made from a combination of metallic and polymer (e.g., plastic) materials. In some embodiments, solder balls 208 may have a lower elastic modulus than solder balls 206. In some embodiments, solder balls 208 may have a lower CTE than solder balls 206. In some embodiments, solder balls 208 may have a greater toughness than solder balls 206. In some embodiments, solder balls 208 may have a higher tensile strength (e.g., ultimate tensile strength) than solder balls 206.

As shown in FIG. 4A, solder balls 206 and solder balls 208 may be arranged in a plurality of rows and/or columns that form an array (e.g., a square or rectangular array). For instance, the depicted example shows two hundred total solder balls that are arranged in ten horizontal rows and twenty vertical columns. However, the total number of solder balls, and their arrangement are not necessarily limited to this specific configuration, which is provided for illustrative purposes. Fewer or greater numbers of solder balls may be included in other embodiments, and they may be arranged in fewer or greater numbers of rows/columns, or in other patterns.

In some embodiments, as shown, solder balls 208 are positioned at least at one or more of the corners of the BGA. In some embodiments, solder balls 208 are positioned at all of the corners of the BGA. In some embodiments, solder balls 208 are only positioned at one or more corners of the BGA. In some embodiments, the corners of the BGA refer to the end positions of the peripheral rows and/or columns of the BGA. The peripheral rows and/or columns in turn may refer to the rows and/or columns that are located along the outermost edge of the BGA. In some embodiments, where the BGA fits within the footprint of semiconductor device 202, the peripheral rows and/or columns may be the rows and/or columns that are closest to each of the lateral sides of semiconductor device 202 (e.g., lateral sides 202a, 202b, 202c, 202d). In some embodiments, the peripheral rows and/or columns the BGA may be the rows and/or columns that are furthest from the center of the BGA.

FIG. 4B provides a cross-sectional view of semiconductor device package 200a taken across the plane designated by line 4B-4B in FIG. 4A (along the first column of solder balls). As shown, each solder ball 206 and solder ball 208 may be attached to a separate bond pad 204 on a surface of semiconductor device 202. In some embodiments, as shown in FIG. 4C, semiconductor device package 200a further includes a substrate 210 that is electrically and/or mechanically coupled to semiconductor device 202 by solder balls 206 and solder balls 208. Substrate 210 may include, for example, a PCB, a carrier, and/or another semiconductor device, etc. In some embodiments, a surface of substrate 210 includes a plurality of contact pads 212 that are each configured to contact a separate solder ball 206 or 208. To connect semiconductor device 202 with substrate 210, semiconductor device 202 may be positioned such that solder balls 206 and 208 are brought into alignment with contact pads 212, and then semiconductor device 202 and substrate 210 are moved toward each other until solder balls 206 and 208 are brought into abutment against contact pads 212. A heating process, e.g, a standard reflow process, may then be used to heat and melt solder balls 206 and 208 onto contact pads 212. In some embodiments, as will be described further herein, solder balls 208 may include an outer solder layer that is selected to melt at a temperature that is the same as or close to the melting temperature of solder balls 206. In some such embodiments, solder balls 206 and solder balls 208 may both be melted in a single reflow process.

In some embodiments, an underfill material (not shown) may be added between semiconductor device 202 and substrate 210 in a manner similar to that described for semiconductor device package 100 shown in FIG. 1E. In other embodiments, semiconductor device package 200a does not include an underfill material between semiconductor device 202 and substrate 210. As discussed, use of underfill material requires additional manufacturing steps as well as added costs. Furthermore, underfill material may produce a fillet that reduces the area on the substrate that is available for mounting other components. Therefore, in some embodiments, it may be preferable not to include an underfill material between semiconductor device 202 and substrate 210. In some embodiments, use of solder balls 208 in addition to solder balls 206 allows for a better match between the CTE of the substrate and the CTE of the BGA such that an underfill material is not needed to distribute thermal stresses.

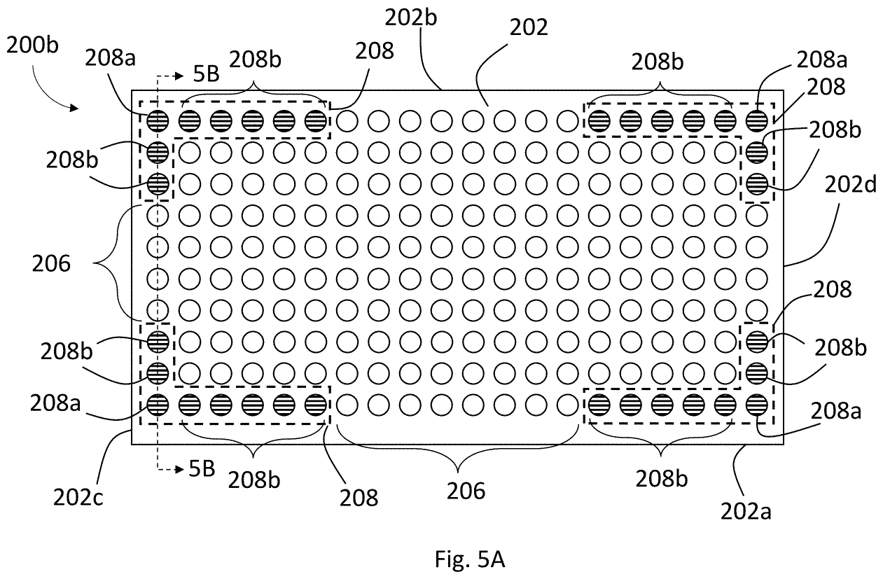

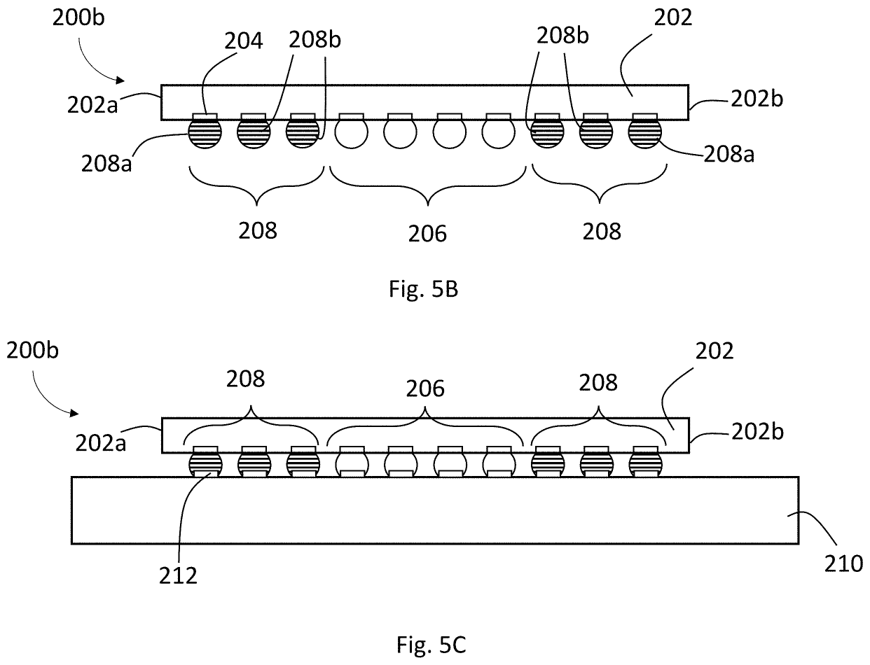

Referring now to FIG. 5A, there is shown a plan view of a BGA of a semiconductor device package 200b according to a further embodiment. Semiconductor device package 200b may be similar to semiconductor device package 200a in that the BGA includes a first subset of solder balls 206 and a second subset of solder balls 208 (shown in the regions designated by the dashed lines). More particularly, second subset of solder balls 208 includes solder balls 208a positioned at one or more corners of the BGA. Second subset of solder balls 208 further includes one or more additional solder balls 208b positioned along the peripheral rows and/or columns of the BGA. At least some of these additional solder balls 208b may be located adjacent to solder balls 208a, according to some embodiments. In some embodiments, each solder ball 208 of the second subset is located in one or more peripheral rows and/or columns of the BGA. In some embodiments, each solder ball 208 of the second subset is located adjacent to at least one other solder ball 208. In some embodiments, the peripheral rows and/or columns of the BGA may also include one or more solder balls 206 of the first subset. The one or more solder balls 206 of the first subset may be located between sets of solder balls 208b.

FIG. 5B provides a cross-sectional view of semiconductor device package 200b taken across the plane designated by line 5B-5B in FIG. 5A (along the first column of solder balls). As shown, each solder ball 206 and solder ball 208 may be attached to a separate bond pad 204 on a surface of semiconductor device 202. In some embodiments, as shown in FIG. 5C, semiconductor device package 200b further includes a substrate 210 having a plurality of contact pads 212 that are electrically and/or mechanically coupled to semiconductor device 202 by solder balls 206 and solder balls 208 in a manner that is similar to that described above for FIG. 4C. In some embodiments, an underfill material (not shown) may be added between semiconductor device 202 and substrate 210. In other embodiments, an underfill material is not included between semiconductor device 202 and substrate 210.

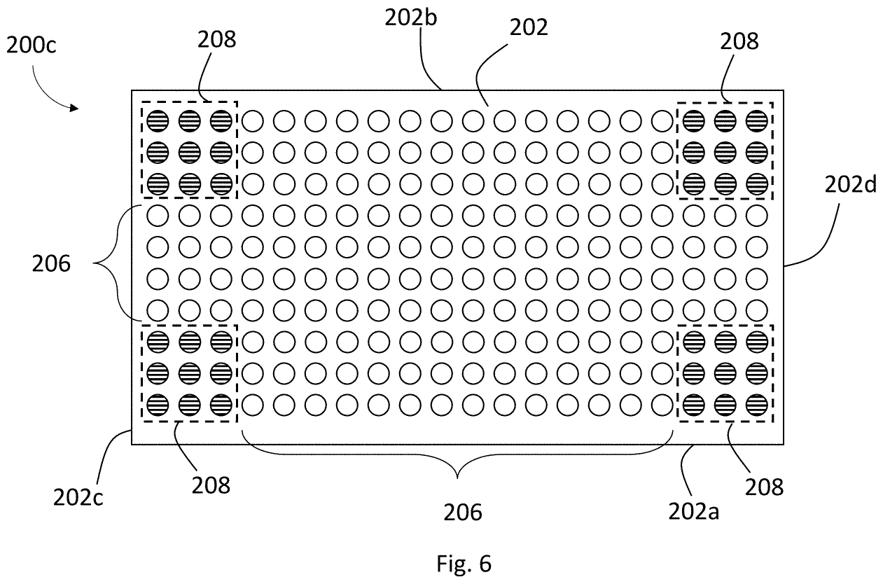

FIGS. 6-11 show plan views of additional example BGAs that have a combination of solder balls 206 and solder balls 208, according to further embodiments. FIG. 6 shows a semiconductor device package 200c having semiconductor device 202 with a BGA that includes a first subset of solder balls 206 and a second subset of solder balls 208 (shown in the regions designated by the dashed lines). The second subset of solder balls 208 includes solder balls 208 positioned at one or more corners of the BGA as well as one or more additional solder balls 208 positioned along the peripheral rows and/or columns of the BGA that may be adjacent to the corners. Solder balls 208 are not necessarily limited to the peripheral rows and/or columns of the BGA. As further shown in this example embodiment, second subset of solder balls 208 may include solder balls 208 in one or more rows and/or columns that are adjacent to the peripheral rows and/or columns of the BGA. For example, semiconductor device package 200c, in some embodiments, includes one or more solder balls 208 in a second and/or third row or column from a lateral side of semiconductor device 202 (e.g., lateral side 202a, 202b, 202c, or 202d).

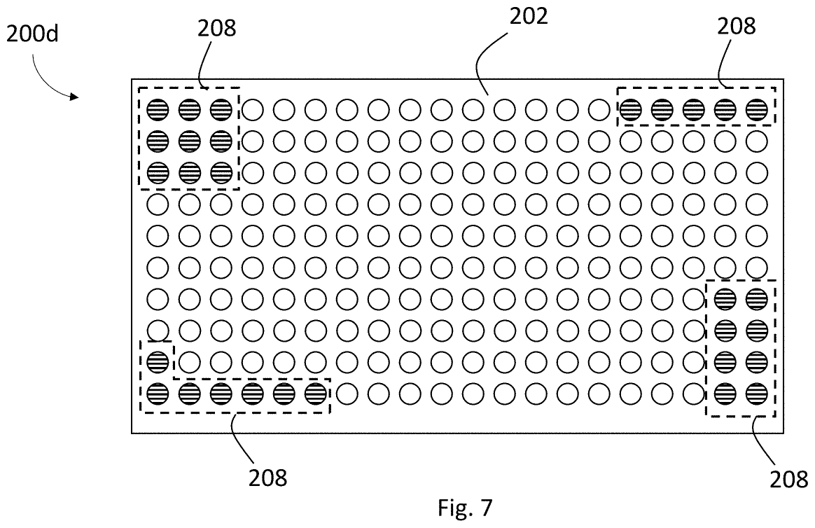

While the arrangement of solder balls 208 may be symmetrical in some embodiments, this is not necessarily the case for other embodiments. FIG. 7 shows a semiconductor device package 200d having semiconductor device 202 with a BGA that includes a first subset of solder balls 206 and a second subset of solder balls 208 (shown in the regions designated by the dashed lines), where solder balls 208 are asymmetrically arranged on the BGA. For example, as illustrated, solder balls 208 may occupy differently shaped or differently sized corner regions on the BGA.

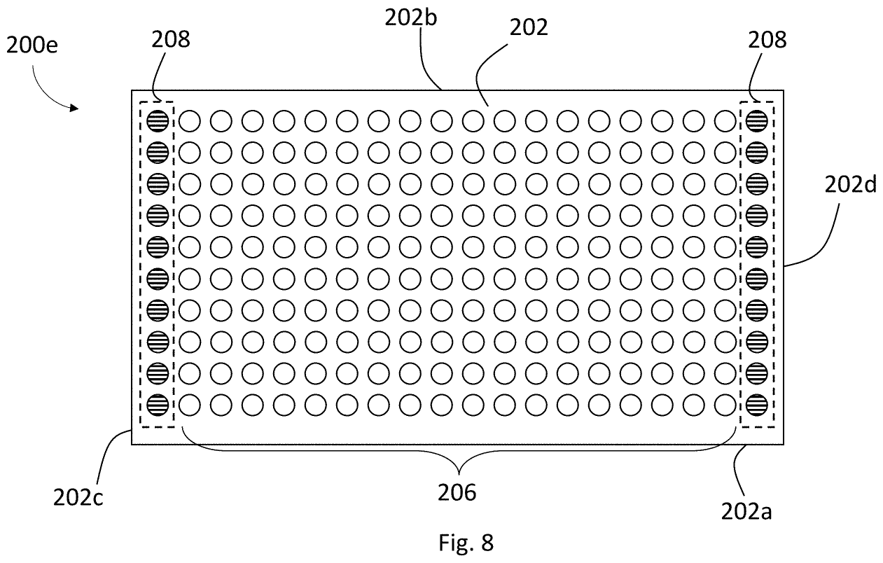

In further embodiments, solder balls 208 may occupy one or more entire rows and/or columns of a BGA. Some such embodiments are shown, for example, in FIGS. 8-11. FIG. 8 shows a semiconductor device package 200e having semiconductor device 202 with a BGA that includes a first subset of solder balls 206 and a second subset of solder balls 208 (shown in the regions designated by the dashed lines), where one or more columns of the BGA is composed entirely of solder balls 208. In some such embodiments, at least the peripheral columns of the BGA are composed entirely of solder balls 208, the peripheral columns being, for example, the columns closest to lateral sides 202c and 202d of semiconductor device 202 in the illustrated embodiment. In some embodiments, at least the ends of each row of the BGA is occupied by solder balls 208. In some such embodiments, each solder ball 206 of the first subset is located between at least two solder balls 208 in the same row.

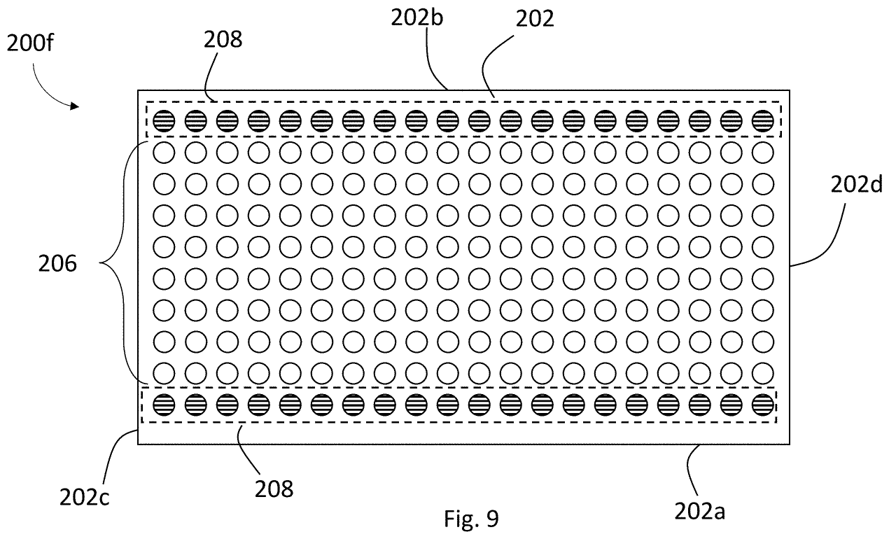

FIG. 9 shows semiconductor device package 200f having semiconductor device 202 with a BGA that includes a first subset of solder balls 206 and a second subset of solder balls 208 (shown in the regions designated by the dashed lines), where one or more rows of the BGA is composed entirely of solder balls 208. In some such embodiments, at least the peripheral rows of the BGA are composed entirely of solder balls 208, the peripheral rows being, for example, the rows closest to lateral sides 202a and 202b of semiconductor device 202 in the illustrated embodiment. In some embodiments, at least the ends of each column of the BGA are occupied by solder balls 208. In some such embodiments, each solder ball 206 of the first subset is located between at least two solder balls 208 in the same column.

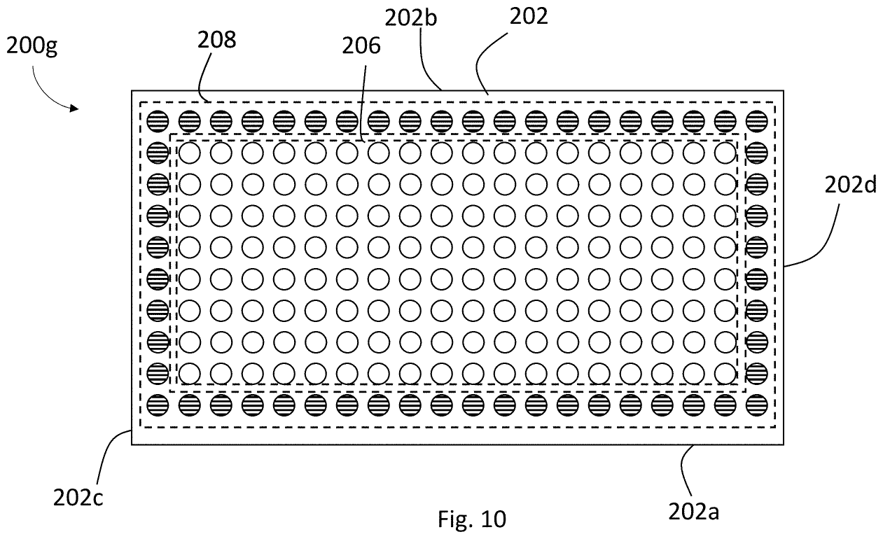

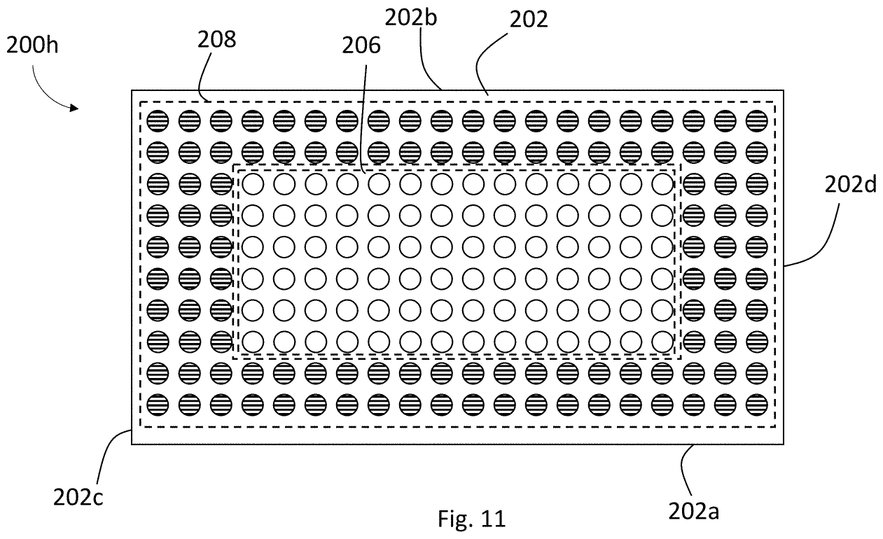

FIG. 10 shows semiconductor device package 200g having semiconductor device 202 with a BGA that includes a first subset of solder balls 206 and a second subset of solder balls 208 (shown in the regions designated by the dashed lines), where one or more rows and one or more columns of the BGA is composed entirely of solder balls 208. In some embodiments, each of the peripheral rows and columns of the BGA is composed entirely of solder balls 208. In some embodiments, at least the ends of each row and the ends of each column of the BGA are occupied by solder balls 208. As described previously, solder balls 208 are not necessarily limited to the peripheral rows/columns of a BGA. FIG. 11 shows semiconductor device package 200h having semiconductor device 202 with a BGA that includes a first subset of solder balls 206 and a second subset of solder balls 208 (shown in the regions designated by the dashed lines), where solder balls 208 occupy one or more rows and/or columns adjacent to the peripheral rows/columns. In some embodiments, second subset of solder balls 208 surrounds the first subset of solder balls 206. In some such embodiments, each solder ball 206 of the first subset is located between at least two solder balls 208 in the same column and is located between at least two solder balls 208 in the same row.

While not particularly illustrated, each of semiconductor device packages 200c, 200d, 200e, 200f, 200g, 200h may further include a substrate that is electrically and/or mechanically coupled to semiconductor device 202 by solder balls 206 and solder balls 208 according to some embodiments. In some embodiments, the substrate may include a plurality of contact pads that are connected to solder balls 206 and solder balls 208 in a manner that is similar to that described above for FIG. 4C. The substrate may include, for example, a PCB, a chip carrier, and/or another semiconductor device.

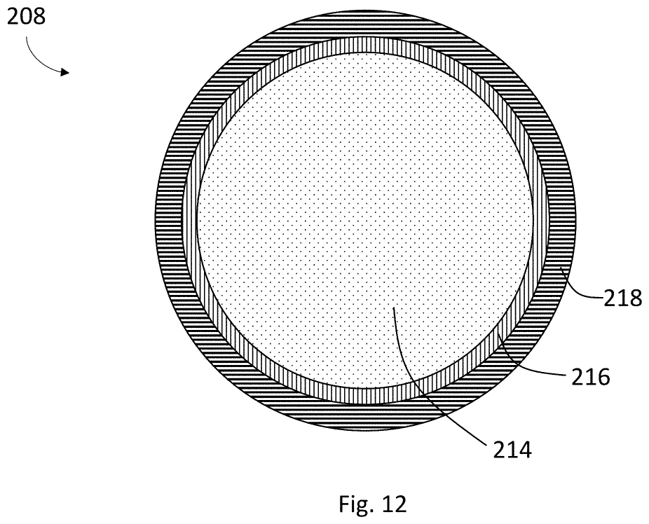

As discussed, in some embodiments, each solder ball 208 of the second subset may be made from a combination of metallic and polymer (e.g., plastic) materials. In some embodiments, solder balls 208 may have a lower elastic modulus than solder balls 206 of the first subset. In some embodiments, solder balls 208 may have a lower CTE than solder balls 206 of the first subset. In some embodiments, solder balls 208 may have a greater toughness than solder balls 206 of the first subset. In some embodiments, solder balls 208 may have a higher tensile strength (e.g. ultimate tensile strength) than solder balls 206 of the first subset. FIG. 12 is a cross-sectional view of an example solder ball 208 according to certain embodiments. In some embodiments, solder ball 208 includes a core 214 that is surrounded by an outer layer 218. In some embodiments, solder ball 208 further includes one or more inner layers 216 disposed between core 214 and outer layer 218. In some non-limiting examples, core 214 may have a diameter from about 50 μm to about 750 μm, outer layer 218 may have a thickness of about 3 μm to about 30 μm, and inner layer 216 may have a thickness of about 1 μm to about 15 μm.

In some embodiments, core 214 includes or consists of at least one polymer material. In some embodiments, core 214 includes or consists of a thermoplastic. In some embodiments, core 214 includes or consists of a thermosetting plastic. For example, in some embodiments, core 214 may be composed of polystyrene or polyimide. In some embodiments, core 214 includes or consists of one or more thermoplastic materials that can withstand reflow temperatures of at least 175° C. to 250° C. without decomposing or chemically changing.

In some embodiments, outer layer 218 of solder ball 208 includes or consists of a layer of solder. For example, in some embodiments, outer layer 218 is composed of a tin solder, tin alloy solder, tin/lead alloy solder, silver alloy solder, etc. In some embodiments, outer layer 218 is configured to melt (e.g., during a reflow process) in order to attach solder ball 208 to a contact pad of a substrate. In some embodiments, outer layer 218 is composed of the same type of solder that is used for solder balls 206 of the first subset. In some embodiments, the solder of outer layer 218 has a melting point that is the same or approximately the same (e.g., ±10° C.) as the melting point of solder balls 206. In some such embodiments, having the same or approximately the same melting point allows both solder balls 206 and outer layer 218 of solder balls 208 to melt during the same reflow process.

In some embodiments, one or more inner layers 216 are disposed between core 214 and outer layer 218. In some embodiments, one or more inner layers 216 includes one or more metal and/or metal alloy layers. In some embodiments, the metal and/or metal alloy layers of inner layer 216 has a melting temperature that is greater than the melting point of outer layer 218. In some embodiments, the metal and/or metal alloy layers of inner layer 216 has melting temperature that is greater than the reflow temperature range (e.g., 175° C. to 250° C.) such that inner layer 216 does not melt during the reflow process. In some embodiments, inner layer 216 is configured to contain the polymer material of core 214, which may melt during the reflow process. In some embodiments, inner layer 216 includes, for example, one or more layers of copper, nickel, silver, or a combination thereof.

In some embodiments, solder balls 208 may have a substantially lower elastic modulus (e.g, Young's modulus) in comparison to solder balls 206. In some embodiments, solder balls 208 may have an elastic modulus that is less than 20 GPa, preferably less than 10 GPa. For example, in some embodiments, solder balls 208 may have an elastic modulus of about 3 GPa to about 7 GPa, e.g., about 5 GPa. In contrast, solder balls 206, which may be composed entirely of metallic solder (e.g., tin alloy, lead/tin alloy, tin-silver-copper alloy, etc.), and may have an elastic modulus that is greater than 20 GPa, or greater than 30 GPa. For example, in some embodiments, solder balls 206 may have an elastic modulus of about 32 GPa. In other embodiments, solder balls 206 have an elastic modulus that is greater than 40 GPa, for example, from 40 GPa to 60 GPa. In some embodiments, solder balls 206 have an elastic modulus that may be at least two to at least six times greater than the elastic modulus of solder balls 208. In some embodiments, core 214 of polymer material contributes to the relatively low elastic modulus of solder balls 208 that allows solder balls 208 to better withstand thermally and/or mechanically induced strain than solder balls 206.

In some embodiments, solder balls 208 may have a substantially higher tensile strength (e.g., ultimate tensile strength) in comparison to solder balls 206. Ultimate tensile strength is the maximum stress that a material can withstand while being stretched or pulled before breaking. In some embodiments, for example, solder balls 206 may be composed of an alloy (e.g., Sn—Ag—Cu alloy) having an ultimate tensile strength of about 40 MPa to about 50 MPa. Solder balls 208, meanwhile, may have an ultimate tensile strength of greater than 60 MPa. In some embodiments, solder balls 208 have an ultimate tensile strength from about 80 MPa to about 100 MPa, for example, 90 MPa. In some embodiments, solder balls 208 may have an ultimate tensile strength that is at least 1.5 to at least 2.5 times greater than the ultimate tensile strength of solder balls 206.

In some embodiments, not all of solder balls 206 and/or 208 are necessarily coupled electrically to semiconductor device 202. In some embodiments, one or more solder ball 206 and/or solder ball 208 may be electrically isolated from semiconductor device 202 such that electrical signals are not conveyed to/from semiconductor 202 through the one or more electrically isolated solder balls. In some such embodiments, the one or more electrically isolated solder balls may be included to provide mechanical connection between semiconductor device 202 and a substrate without providing an electrical connection. In some embodiments, at least a portion of solder balls 208 of the second subset are electrically isolated from semiconductor device 202. In some embodiments, for example, any solder ball 208 located in a peripheral row and/or column of the BGA may be configured to be electrically isolated from semiconductor device 202. In some embodiments, all of solder balls 208 may be electrically isolated from semiconductor device 202. In some embodiments, some or all of solder balls 206 of the first subset are electrically coupled to semiconductor device 202.

It should be understood that various changes, substitutions, and alterations can be made herein without departing from the spirit and scope of the invention as defined by the appended claims. It should also be apparent that individual elements identified herein as belonging to a particular embodiment may be included in other embodiments of the invention. Moreover, the scope of the present application is not intended to be limited to the particular embodiments of the process, machine, manufacture, and composition of matter, means, methods and steps described in the specification. The scope of the invention also is not meant to be limited by the title or the abstract, as these parts of the application are provided to facilitate searching specific features disclosed herein. As one of ordinary skill in the art will readily appreciate from the disclosure, processes, machines, manufacture, composition of matter, means, methods, or steps, presently existing or later to be developed that perform substantially the same function or achieve substantially the same result as the corresponding embodiments described herein may be used according to the present disclosure.

What is claimed is:

1. A semiconductor device package, comprising:
a semiconductor device having a ball grid array disposed on a side of the semiconductor device, the ball grid array comprising:
a first subset of solder balls composed of a first material; and
a second subset of solder balls composed of a second material that is different than the first material.

2. The semiconductor device package of claim 1, wherein the first material is a metallic solder, and wherein the second material is a composite material comprising at least one polymer.

3. The semiconductor device package of claim 2, wherein the composite material includes a core comprising the at least one polymer and further comprises a solder layer surrounding the core.

4. The semiconductor device package of claim 3, wherein the solder layer of the second material has a melting temperature that is the same as the melting temperature of the metallic solder of the first material.

5. The semiconductor device package of claim 2, wherein the second material further comprises one or more inner layers disposed between the core and the solder layer, the one or more inner layers comprising one or more metallic layers having a melting temperature greater than the melting temperature of the solder layer.

6. The semiconductor device package of claim 1, wherein the first material has an elastic modulus that is greater than an elastic modulus of the second material.

7. The semiconductor device package of claim 1, wherein at least a portion of the second subset of solder balls are positioned at one or more corners of the ball grid array.

8. The semiconductor device package of claim 7, wherein a solder ball of the second subset of solder balls is positioned at each corner of the ball grid array.

9. The semiconductor device package of claim 1, wherein the ball grid array includes one or more peripheral rows and/or one or more peripheral columns that are composed entirely of solder balls of the second subset of solder balls.

10. The semiconductor device package of claim 9, wherein all of the solder balls of the second subset of solder balls are positioned in the one or more peripheral rows and/or the one or more peripheral columns of the ball grid array.

11. The semiconductor device package of claim 1, wherein each solder ball of the first subset is located between at least two solder balls of the second subset in a same column or row of the ball grid array.

12. The semiconductor device package of claim 1, wherein the first subset of solder balls is surrounded by the second subset of solder balls.

13. The semiconductor device package of claim 1, wherein at least a portion of the second subset of solder balls is electrically isolated from the semiconductor device.

14. The semiconductor device package of claim 1, further comprising a substrate coupled electrically and mechanically to the semiconductor device by the ball grid array.

15. The semiconductor device package of claim 14, wherein an underfill material is not present between the semiconductor device and the substrate.

16. A ball grid array for connecting a semiconductor device to a substrate, the ball grid array comprising:
a first subset of solder balls composed entirely of a metallic solder; and
a second subset of solder balls comprising a polymer core, a solder layer surrounding the polymer core, and one or more metallic layers disposed between the polymer core and the solder layer,
at least a portion of the second subset of solder balls being located on a periphery of the ball grid array.

17. A semiconductor device package, comprising:
substrate means for providing electrical interconnections;
integrated circuit means for outputting electrical signals to the substrate means;
first solder ball means disposed between the integrated circuit means and the substrate means for electrically coupling the integrated circuit means to the substrate means; and
second solder ball means disposed between the integrated circuit means and the substrate means for mechanically coupling the integrated circuit means to the substrate, the second solder ball means comprising a material of lower elastic modulus and/or higher tensile strength than the first solder ball means.

18. The semiconductor device package of claim 17, wherein the first solder ball means and the second solder ball means are arranged in an array, wherein the second solder ball means are positioned at least at one or more corners of the array.

19. The semiconductor device package of claim 18, wherein the first solder ball means is surrounded by the second solder ball means.

20. The semiconductor device package of claim 17, wherein at least a portion of the second solder ball means is electrically isolated from the integrated circuit means.
